(19) United States
(12) Patent Application Publication
(10) Pub. No.: US 2026/0129814 A1
(43) Pub. Date: May 7, 2026

(54) HEAT DISSIPATION MECHANISM AND CHARGING DEVICE

(71) Applicant: HON HAI PRECISION INDUSTRY CO., LTD., New Taipei (TW)

(72) Inventor: HSIAO-LUN CHEN, New Taipei (TW)

(21) Appl. No.: 18/973,443

(22) Filed: Dec. 9, 2024

(30) Foreign Application Priority Data
Nov. 6, 2024 (CN) 202422702762.8

(51) Int. Cl. H05K 7/20; H02J 7/00; H05K 5/02

(52) U.S. Cl. CPC H05K 7/20909; H05K 5/0214; H05K 7/20145; H02J 7/70

(57) ABSTRACT

A heat dissipation mechanism is applied in a charging device. The charging device includes a housing and power modules. The housing defines with an air inlet opening. The heat dissipation mechanism includes an air inlet member and at least one wind guiding member. The air inlet member is located between the air inlet opening and the power modules and drives an airflow to flow from the air inlet opening to the power modules. The air inlet member includes a plurality of first driving parts and a plurality of wind guiding plates. The wind guiding plates are rotatably mounted on the housing. Each of the wind guiding plates is connected to a corresponding first driving part. Each of the first driving parts drives the corresponding wind guiding plate to rotate, for driving the airflow towards the power modules. A charging device is also provided.

### TECHNICAL FIELD

The present application generally relates to new energy technology, and particularly to a heat dissipation mechanism and a charging device.

### BACKGROUND

A charging pile is used to charge the new energy vehicle. Currently, the charging pile may include multiple power modules. While charging the vehicle, the charging pile may determine a specification of batteries in the vehicle for confirming a charging power provided to the vehicle, and start a partial of the power modules. A sum discharging power of the switched on power modules corresponds to the charging power provided to the vehicle, thereby the charging pile charges the new energy vehicle.

However, heat dissipation of the charging pile is achieved by turning on all heat dissipation fans in the charging pile at the same time, it is unable to centralize heat dissipation on the switched on power modules, and the heat dissipation effect of the switched on power modules is poor.

There is room for improvement in the art.

### BRIEF DESCRIPTION OF THE DRAWINGS

Implementations of the present application will now be described, by way of example only, with reference to the attached figures.

FIG. 1 is a diagram illustrating a first embodiment of a charging device according to the present application.

FIG. 2 is a system diagram illustrating an embodiment of a heat dissipation mechanism according to the present application.

FIG. 3 is a diagram illustrating a second embodiment of a charging device according to the present application.

### DETAILED DESCRIPTION

The following clearly describes the technical solution in embodiments of this application with reference to the accompanying drawings in the embodiments of the application.

The “a plurality of” in the embodiments of the application means two or more. In addition, it is understood that, in the description of the application, terms, such as “first”, “second”, are merely used for a purpose of distinguishing between descriptions, but cannot be understood as indication or implication of relative importance, and cannot be understood as an indication or implication of a sequence.

In the description of the application, terms, such as “exemplary”, “for example”, is used to represent giving an example, an illustration, or a description. Any embodiment or design scheme described as “example” or “for example” in embodiments of the application should not be explained as being more preferred or having more advantages than another embodiment or design scheme. Exactly use of the terms “example”, “for example”, or the like is intended to present a related concept in a specific manner.

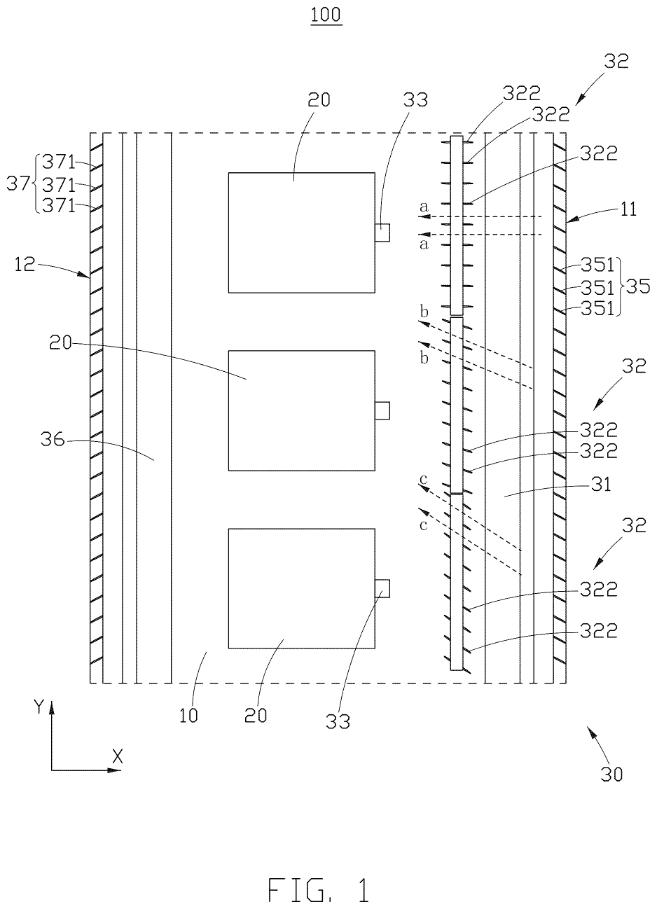

Referring to FIG. 1, FIG. 1 shows a diagram of a charging device 100 provided by the present application. The charging device 100 may be electrically connected to a vehicle (not shown), and establishes an electrical connection with batteries in the vehicle through an internal circuit of the vehicle. The charging device 100 may use a charging power corresponding to a specification of batteries in the vehicle to charge the batteries, thus the vehicle is charged.

It is understood that, while charging the vehicle, the charging power of the vehicle may be equal to a discharging power of the charging device 100.

In an embodiment of the present application, a type of the vehicle is not limited. For example, the vehicle may use a battery for storing energy and be driven by electrical power, such as an electric passenger car, a truck, a motorcycle, a purpose build vehicle, an agricultural machine, but not limited. The vehicle may be a manual driven car or an automated driven car, the embodiments in the present application does not limit.

In other embodiments, the charging device 100 may charge other energy storage devices or working devices besides the vehicle. The energy storage devices may be outdoor power supplies, and uninterrupted power supplies, and the like, but not limited. The working devices may be aerial vehicles, but not limited.

In an embodiment of the present application, the type of the charging device 100 is not limited. For example, the charging device 100 may be a direct current (DC) charging pile or an alternating current (AC) charging pile.

It is understood that, a width direction and a height of the charging device 100 are defined as a first direction and a second direction. For example, the first direction may be a X direction as shown in FIG. 1 and an negative direction against the X direction, the second direction may be a Y direction as shown in FIG. 1 and an negative direction against the Y direction.

In one embodiment, the charging device 100 may include a housing 10 and a plurality of power modules 20. Opposite sides of the housing 10 defines an air inlet opening 11 and an air outlet opening 12 respectively. The plurality of the power modules 20 are received in the housing 10, and is fixed on inner sidewalls of the housing 10. The plurality of the power modules 20 are disposed between the air inlet opening 11 and the air outlet opening 12, and the plurality of the power modules 20 is separated from each other along the second direction. Each of the plurality of the power modules 20 may charge the vehicle. By starting a partial of the plurality of the power modules 20, a discharging power of the charging device 100 is equal to a sum charging power of the switched on power modules 20. The charging power of the vehicle is equal to the sum discharging power of the switched on power modules 20. The charging device 100 may determine a specification of batteries in the vehicle and a type of a charging protocol of the vehicle, for confirming a required charging power while charging the vehicle. The charging device 100 further starts corresponding power modules 20 based on predefined rule for charging the vehicle.

It is understood that, the charging device 100 and the to-be-charged vehicle may connect with each other through cables. The charging device 100 may acquires the specification of the batteries through the cables, accomplishes a handshake of the charging protocol, and charges the vehicle. The above process may be executed based on common technology in related field, the detail will not described in the present application.

In one embodiment, the predefined rule of the charging device 100 is not limited in the present application. For example, a maximum power of each of the plurality of the power modules 20 in the charging device 100 is same, the charging device 100 may start the power modules 20 in that order along a direction from up to down. The sum power of the switched on power modules 20 is equal to the required charging power while charging the vehicle.

It should be noted that, the term “equal” in the present application mean a difference between two parameters being in a predefined error range. The predefined error range may be set based on the specifications of the charging device 100 and vehicle, but not limited.

In one embodiment, fixing manners while being fixed mounted or being fixed connection are not limited. For example, the fixing manners may include a welding fixing manner, a screwing fixing manner, a clipping fixing manner, and the like.

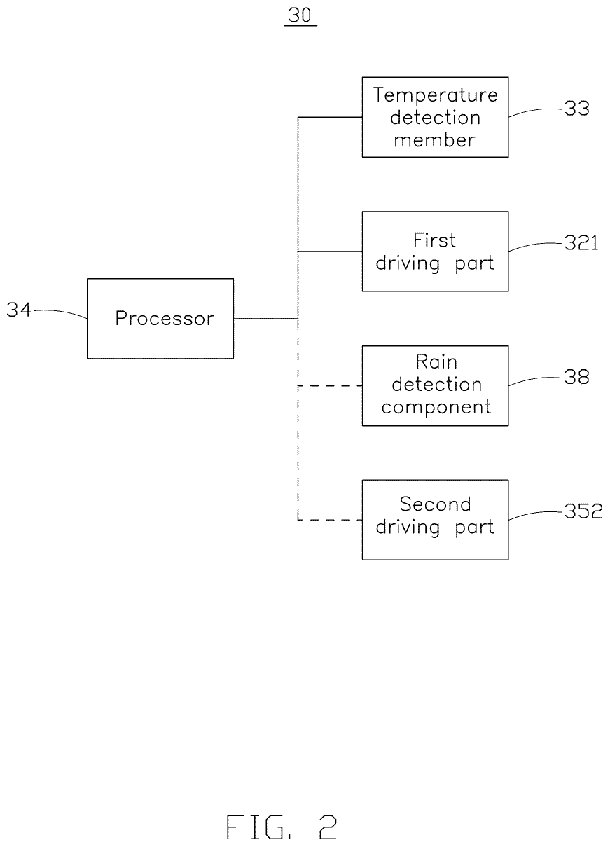

Referring to FIG. 2, in some embodiments, the charging device 100 further includes a heat dissipation mechanism 30. The heat dissipation mechanism 30 may include an air inlet member 31, at least one wind guiding member 32, at least one temperature detection member 33, and a processor 34.

The air inlet member 31 is disposed between the air inlet opening 11 and the plurality of the power modules 20 along the first direction. The air inlet member 31 may be fixed on the housing 10. The air inlet member 31 drives an airflow from the air inlet opening 11 to the plurality of the power modules 20 while working. The airflow passing through some of the plurality of the power modules 20 is flowed out of the housing 10 through the air outlet opening 12.

There are a plurality of the wind guiding members 32. All of the wind guiding members 32 are disposed between the air inlet opening 11 and the plurality of the power modules 20 along the first direction. A number of the wind guiding members 32 may be greater than a number of the power modules 20, and each of the wind guiding members 32 corresponds to one of the power modules 20. Each of the wind guiding members 32 may include at least one first driving part 321 and a plurality of wind guiding plates 322. The plurality of the wind guiding plates 322 is separated from each other along the second direction. Each of the plurality of the wind guiding plates 322 is rotatably connected with the inner sidewalls of the housing 10. A number of the first driving part 321 may be less than or equal to a number of the wind guiding plates 322. Each of the first driving part 321 is connected to corresponding wind guiding plates 322, and drives the corresponding wind guiding plates 322 to rotate.

There are a plurality of the temperature detection members 33. Each of the temperature detection members 33 corresponds to one of the power modules 20, and is disposed on a side of the corresponding power module 20. Each of the temperature detection members 33 may detect a temperature of the corresponding power module 20 and outputs temperature detection information. The processor 34 communicates with each of the temperature detection members 33 and each of the first driving parts 321. The processor 34 may receive the temperature detection information of all of the temperature detection members 33, and determine the switched on power module 20 based on the received temperature detection information. The processor 34 may switch on the first driving parts 321, for driving the corresponding wind guiding plates 322 to rotate, thus the airflow is guided to the switched on power modules 20.

It is understood that, the manner of rotatably connecting is achieved by a rotatable connection member, which causes two portions to rotate in related with each other. In one embodiment, a type of the rotating connection member is not limited. For example, the rotating connection member may include a bearing, a pin shaft, a hinge, and the like.

It is understood that, the first driving parts 321 may be an electrical or pneumatic members with a driving function of rotating. In one embodiment of the present application, a type of the first driving parts 321 is not limited. For example, the first driving parts 321 may be driving parts for directly driving objects to rotate, such as motors or rotary cylinders, which are, but does not limit. For another example, the first driving parts 321 may be driving parts for driving the objects to move straight, such as linear motors, or cylinders, and the like, but does not limit. The first driving parts 321 may combinate with a transmission structure to form an assembly, such as a link structure, or a rack and pinion structure, and the like.

Exemplary, the wind guiding members 32 may correspond to the power modules 20 in an one-to-one relationship, each of the wind guiding members 32 includes one of the first driving parts 321. The first driving parts 321 may drive the corresponding wind guiding plates 322 to rotate synchronously. The wind guiding plates 322 may connect with each other through the transmission mechanism, the first driving parts 321 connect with each other through the transmission mechanism and drive the transmission mechanism to move, for driving the wind guiding plates 322 to rotate synchronously. The transmission mechanism may be a synchronous belt or wheel structure, or rack and pinion structure, or a link structure.

It is understood that, when the first driving parts 321 are the cylinders or the rotary cylinders, the first driving parts 321 may include a solenoid valve being communicated with the processor 34. Thus, the first driving parts 321 establishes communication connection with the processor 34.

In one embodiment, a manner of the communication connection is not limit. For example, the communication connection may be a wired communication connection through devices, such as signal cables. For another example, the communication connection may be a wireless communication connection based on technologies, such as 3G, 4G, 5G, BLUETOOTH®, a Wireless Local Area Network (WLAN).

In one embodiment of the present application, a type of each of the temperature detection members 33 is not limited. For example, each of the temperature detection members 33 may be a temperature sensor or a thermosensitive resistor, and the like.

In one embodiment of the present application, a mounted position of each of the temperature detection members 33 is not limited. For example, the temperature detection members 33 may be fixed mounted on the inner sidewalls of the housing 10. For another example, each of the temperature detection members 33 may be fixed with the corresponding power module 20.

In one embodiment of the present application, a type of the processor 34 is not limited. For example, the processor 34 may be a central processing unit (CPU), and also may be other general purpose processor, a digital signal processor (DSP), an Application Specific Integrated Circuit (ASIC), a Field-Programmable Gate Array (FPGA) or other programmable logic devices, discrete gate or transistor logic devices, discrete hardware components, and so on. The general purpose processor may be a microprocessor or any conventional processor.

It is understood that, the processor 34 may determines the temperature of each of the power modules 20 based on the received temperature detection information. Because of the heat generated while the power module 20 works for charging the vehicle, the temperature of the switched on power module 20 is higher than the temperature of the switched off power module 20. The processor 34 may determines whether there is the power module 20 with the temperature exceeded a predefined temperature threshold value, and determines that the power module 20 with the temperature exceeded the predefined temperature threshold value is switched on. Or, the processor 34 may compares the temperatures of the power modules 20, and determines the power module 20 with a higher temperature being switched on. Then, the processor 34 may switch on a partial of the first driving parts 321 in some of the wind guiding members 32. Thus, the wind guiding plates 322 of the wind guiding members 32 face to the switched on power modules 20, for guiding the airflow entranced into the housing 10 at the air inlet opening 11 to the switched on power module 20. A quantity of the airflow passing through the switched on power modules 20 is increased, and an air-cooled effect of the switched on power module 20 is improved. The temperature threshold value may be a temperature reached by the power module 20 after switched on. A detail value may be adjusted based on the type of the power module 20, and the embodiment of the present application does not limit.

Further, after determining the switched on power modules 20 in the power modules 20, the processor 34 controls the first driving parts 321 based on a predefined rule. In one embodiment of the present application, detail content of the predefined rule is not limit. For example, when there are M power modules 20 distanced from each other along the second direction and an Nth to (N+1)th power modules 20 from up to down are switched on, the predefined rule may control the wind guiding plates 322 corresponding to the power modules 20 disposed upon the Nth power module 20 to rotate in an anti-clock direction, and control the wind guiding plates 322 corresponding to the power modules 20 disposed below the (N+1)th power module 20 to rotate in an clockwise direction. A rotating angle of each of the rotated wind guiding plates 322 relates to a sequence of the corresponding power module 20 in the power modules 20. N is an integer larger than or equal to 1, and M is larger than (N+1).

Exemplary, as shown in FIG. 1, there are three power modules 20 in the charging device 100, and three wind guiding members 32 corresponding to the three power modules 20. The three power modules 20 are sequenced from up to down, and the three wind guiding member 32 are sequenced from up to down. When a first power module 20 is switched on, and a second and third power modules 20 are not start, the wind guiding plates 322 of a first wind guiding member 32 rotates to be parallel with the first direction, for guiding the airflow A to flow along the first direction to the switched on first power module 20. The wind guiding plates of a second to third wind guiding members 32 may rotate to be angled with the first direction in an acute angle, for guiding an airflow B and an airflow C to flow to the switched on first power module 20. An angle of each of the wind guiding plates 322 of the second wind guiding member 32 and the first direction is less than an angle of each of the wind guiding plates 322 of the third wind guiding member 32 and the first direction.

In other embodiments, the heat dissipation mechanism 30 may do not include the temperature detection members 33. The processor 34 may communicates with the power modules 20. The processor 34 may determines whether the power modules 20 works, and switch on the first driving parts 321, for driving the wind guiding plates 322 corresponding to the worked first driving parts 321 towards to the switched on power modules 20, thus the quantity of the airflow passing through the switched on power modules 20 is increased.

It is understood that, when the power module 20 works, a voltage or current on pins or in circuits of the power module 20 may be changed. The processor 34 may monitor the change of the voltage or the current on the pins or in the circuits of the power module 20, for determining whether the power module 20 starts.

In some embodiments, the heat dissipation mechanism 30 may further include an air inlet louver 35, an air outlet member 36, and an air outlet louver 37.

At least a part of the air inlet louver 35 is be received in the air inlet opening 11 and covers the air inlet opening 11. At least a part of the air outlet louver 37 is be received in the air outlet opening 12 and covers the air outlet opening 12. Both of the air inlet louver 35 and the air outlet louver 37 are fixed on the housing 10.

The air outlet member 36 may disposed between the air outlet opening 12 and the power modules 20 along the first direction. The air outlet member 36 may be fixed on the housing 10. The air outlet member 36 works to drive the airflow to flow from the power modules 20 to the air outlet opening 12. The air outlet member 36 cooperates with the air inlet member 31, for driving the airflow to flow from the air inlet opening 11 to the air outlet opening 12 by passing the power modules 20. Therefore, the heat of the charging device 100 is air-cooled dissipated.

It is understood that, both of the air inlet louver 35 and the air outlet louver 37 are defined a plurality of wind gaps, the airflow may entrance into the housing 10 through the wind gaps of the air inlet louver 35 and exit from the housing 10 through the wind gaps of the air outlet louver 37.

It is understood that, both of the air inlet member 31 and the air outlet member 36 are portions formed by a plurality of fans or air blowers. A flowing direction of the airflow guided by the air inlet member 31 and the air outlet member 36 are same.

In some embodiments, the air inlet louver 35 includes a plurality of air inlet blades 351. The plurality of the air inlet blades 351 is separated from each other along the second direction, and a gap between two adjusting air inlet blades 351 defines the wind gap of the air inlet louver 35. The air outlet louver 37 includes a plurality of air inlet blades 371. The plurality of the air outlet blades 371 is separated from each other along the second direction, and a gap between two adjusting air outlet blades 371 defines the wind gap of the air outlet louver 37.

Each of the air inlet blades 351 and each of the air outlet blades 371 may be in a shielding state. When in the shielding state, the air inlet blades 351 are angled with the corresponding power module 20. A distance between a top end of the air inlet blade 351 and the corresponding power module 20 along the first direction is less than a distance between a bottom end of the air inlet blade 351 and the corresponding power module 20. When in the shielding state, the air outlet blades 371 are angled with the corresponding power module 20. A distance between a top end of the air outlet blade 371 and the corresponding power module 20 along the first direction is less than a distance between a bottom end of the air outlet blade 371 and the corresponding power module 20.

It is understood that, when all of the air inlet blades 351 and the air outlet blades 371 are in the shielding state, the air inlet blades 351 and the air outlet blades 371 are titled downwardly along a direction facing to an outer of the housing 10. The air inlet blades 351 and the air outlet blades 371 being titled downwardly may receive rain water and guide the rain water to flow downwardly along a direction away from the housing 10. Therefore, the air inlet blades 351 and the air outlet blades 371 may decrease the rain water flowed in to the charging device 100 while raining, a safety of the charging device 100 is improved.

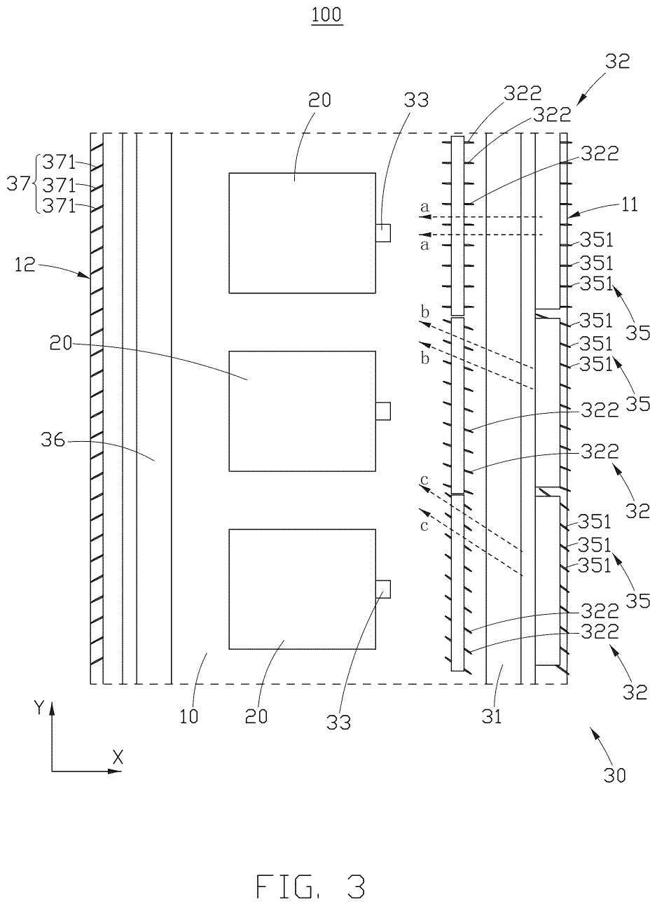

Referring to FIG. 3, in some embodiments, the air outlet blades 371 is in the shielding state. The air inlet member 351 may further include a plurality of second driving parts 352. A number of the second driving parts 352 may be less than or equal to the number of the air inlet blades 351. Each of the air inlet blades 351 corresponds to one of the power modules 20. Each of the power modules 20 corresponds to at least two adjacent air inlet blades 351. Each of the second driving parts 352 is connected to a corresponding air inlet blade 351, and drives the corresponding air inlet blade 351 to rotate. Each of the second driving parts 352 are communicated with the processor 34.

The heat dissipation mechanism 30 further include a rain detection member 38. The rain detection member 38 may be communicated with the processor 34. The rain detection member 38 is disposed on the outer sidewall of the housing 10, and is fixed on the housing 10. The rain detection member 38 may detect whether a climate where the charging device 100 is located is raining, and output rain detection information to the processor 34. The processor 34 may determine that whether the climate where the charging device 100 is located is raining. When determining the climate where the charging device 100 is located is raining, the processor 34 switches on each of the second driving parts 352, and each of the air inlet blades 351 rotate into the shielding state. When determining the climate where the charging device 100 is located is not raining and there is at least one power module 20 is switched on, the processor 34 switches on at least part of the second driving parts 352, for driving the corresponding air inlet blades 351 to rotate and towards the at least one switched on power modules 20. Therefore, the airflow is guided to the at least switched on power modules 20.

In one embodiment of the present application, a type of the rain detection member 38 is not limit. For example, the rain detection member 38 may be a detection member for directly detecting the rain existed, such as a rain sensor or a water immersion sensor, and the like. For another example, the rain detection member 38 may include a water collection box and a fluid level sensor. Using the fluid level sensor to detect a fluid level in the water collection box, the rain is determined.

It is understood that, a type of the second driving part 352 may be the same as the type of the first driving part 321, no details will described.

In one embodiment of the present application, mounting positions of the first driving parts 321 and the second driving parts 352 are not limited. For example, the first driving parts 321 and the second driving parts 352 are fixed mounted on a mounting frame fixedly mounted on the inner sidewall of the housing 10, thus the first driving parts 321 and the second driving parts 352 are fixed mounted on the housing 10.

It is understood that, the processor 34 may control the wind guiding plates 322 towards to the switched on power module 20 and switch on the second driving parts 352, while there is no rain and there is at least one power module 20 is switched on, thus the air inlet blades 351 face to the switched on power module 20, for increasing a fluency and the flux of the airflow flowed to the switched on power module 20, and a heat dissipation effect of the switched on power module 20 is enhanced. The principle of controlling the second driving parts 352 by the processor 34 based on the rain detection information is the same as or similar to the principle of controlling the first driving parts 321 by the processor 34 based on the temperature detection information. The principle of determining whether there is rain based on the rain detection information is the same as or similar to the principle of the determining whether the power module 20 is switched on based on the temperature detection information by the processor 34, no detail will described again.

By using the heat dissipation mechanism 30 and the charging device 100 of the present application, while charging the vehicle, the charging device 100 starts a partial of the power module 20 based on the charging power required by the charged vehicle, the wind guiding plates 322 of the wind guiding member 32 rotate and face to the switched on power module 20, the air inlet blades 351 of the air louver 35 rotate and face to the switched on power module 20. Therefore, while the air inlet member 31 and the air outlet member 36 work, an air flow of the air passing through the switched on power module 20 is increased, an air-cooled effect of the switched on power module 20 is improved, and a service time of the charging device 100 is increased.

For those skilled in the art, it is apparent that the present disclosure is not limited to the details of the demonstrative embodiments mentioned above, and that the present disclosure can be realized in other specific forms without departing from the spirit or basic features of the present disclosure. Therefore, from any point of view, the embodiments should be regarded as exemplary and non-limiting. The scope of the present disclosure is defined by the appended claims rather than the above description. Therefore, all changes falling within the meanings and scope of equivalent elements of the claims are intended to be included in the present disclosure.

What is claimed is:

1. A heat dissipation mechanism applied in a charging device; the charging device comprises a housing and a plurality of power modules disposed in the housing; the housing defines an air inlet opening; the heat dissipation mechanism comprising:
an air inlet member to be disposed in the housing, and located between the air inlet opening and the power modules; the air inlet member configured to drive an airflow to flow from the air inlet opening to the plurality of the power modules; and
at least one wind guiding member to be disposed between the air inlet member and the plurality of the power modules; the at least one wind guiding member comprises a plurality of first driving parts and a plurality of wind guiding plates second port; the plurality of the wind guiding plates is rotatably mounted on the housing; each of the plurality of the wind guiding plates is connected to a corresponding first driving part of the plurality of the first driving parts; the first corresponding driving part is configured to drive the wind guiding plate to rotate, for driving the airflow towards at least one power module of the plurality of the power modules being switched on.

2. The heat dissipation mechanism of claim 1, further comprises:
a plurality of temperature detection members to be disposed in the housing, each of the plurality of the temperature detection members corresponds to a power module of the plurality of the power modules, and configured to detect temperature of the corresponding power module and output temperature detection information; and
a processor communicating with the plurality of the temperature detection members and the plurality of the first driving parts; the processor configured to receive the temperature detection information and switch on at least one of the plurality of the first driving parts based on the received temperature detection information.

3. The heat dissipation mechanism of claim 1, further comprises:
a processor communicating with the plurality of the first driving parts and the plurality of the power modules, and configured to detect whether each of the plurality of the power modules is switched on and switch on at least one of the plurality of the first driving members if at least one of the plurality of the power modules is detected switched on.

4. The heat dissipation mechanism of claim 1, further comprises:
an air inlet louver configured to be connected to the housing, and configured to shield the air inlet opening.

5. The heat dissipation mechanism of claim 4, wherein the air inlet louver comprises a plurality of air inlet blades and a plurality of second driving parts; the plurality of the air inlet blades is separated from each other, and is configured to be rotatably connected to the housing; each of the plurality of the second driving parts is configured to drive a corresponding air inlet blade of the plurality of air inlet blades to rotate thereby guiding the airflow towards the at least one power module or the second driving part drives the corresponding air inlet blade into a shielding state wherein the corresponding air inlet blade is titled downwardly, a distance between a top end of the corresponding air outlet blade and the corresponding power module is less than a distance between a bottom end of the corresponding air outlet blade and the corresponding power module.

6. The heat dissipation mechanism of claim 5, further comprises:
a rain detection member to be connected to the housing, and configured to detect whether a climate where the charging device is located is raining and output rain detection information; and
a processor communicating with the rain detection member and the plurality of the second driving parts, and configured to receive the rain detection information and control the plurality of the second driving parts to switch on based on the received rain detection information.

7. The heat dissipation mechanism of claim 1, wherein the plurality of the power modules is disposed between the air inlet opening and an air outlet opening of the housing, and further comprises:
an air outlet member to be disposed in the housing, and located between the plurality of the power modules and the air outlet opening; the air outlet member configured to drive the airflow to flow from the plurality of the power modules to the air outlet opening.

8. The heat dissipation mechanism of claim 7, further comprises:
an air outlet louver to be connected to the housing and configured to shield the air outlet opening.

9. The heat dissipation mechanism of claim 8, wherein the air outlet louver comprises a plurality of air outlet blades; the plurality of the air outlet blades is separated from each other; a distance between a top end of each of the plurality of the air outlet blades and the corresponding power module is less than a distance between a bottom end of the corresponding air outlet blade and the corresponding power module.

10. A charging device comprising:
a housing, a side of the housing defined with an air inlet opening;
a plurality of power modules disposed in the housing; and
a heat dissipation mechanism comprising:
an air inlet member to be disposed in the housing, and located between the air inlet opening and the plurality of the power modules; the air inlet member configured to drive an airflow to flow from the air inlet opening to the plurality of the power modules; and
at least one wind guiding member disposed between the air inlet member and the plurality of the power modules; the at least one wind guiding member comprises a plurality of first driving parts and a plurality of wind guiding plates; the plurality of the wind guiding plates is rotatably mounted on the housing; each of the plurality of the wind guiding plates is connected to a corresponding first driving part of the plurality of the first driving parts; the first corresponding driving part is configured to drive the wind guiding plate to rotate, for driving the airflow towards at least one power module of the plurality of the power modules.

11. The charging device of claim 10, wherein the heat dissipation mechanism further comprises:
a plurality of temperature detection members to be disposed in the housing, each of the plurality of the temperature detection members corresponds to a power module of the plurality of the power modules, and configured to detect temperature of the corresponding power module and output temperature detection information; and
a processor communicating with the plurality of the temperature detection members and the plurality of the first driving parts; the processor configured to receive the temperature detection information and switch on at least one of the plurality of the first driving parts based on the received temperature detection information.

12. The charging device of claim 10, wherein the heat dissipation mechanism further comprises a processor communicating with the plurality of the first driving parts and the plurality of the power modules; the processor is configured to detect whether each of the plurality of the power modules is switched on and switch on at least one of the plurality of the first driving members if at least one of the plurality of the power modules is detected switched on.

13. The charging device of claim 10, wherein the heat dissipation mechanism further comprises an air inlet louver connected to the housing; the air inlet louver is configured to shield the air inlet opening.

14. The charging device of claim 13, wherein the air inlet louver comprises a plurality of air inlet blades and a plurality of second driving parts; the plurality of the air inlet blades is separated from each other, and is configured to be rotatably connected to the housing; each of the plurality of the second driving parts is configured to drive a corresponding air inlet blade of the plurality of the air inlet blades to rotate, thereby guiding the airflow towards the at least one power modules being switched on or the second driving part drives the corresponding air inlet blade into a shielding state, wherein the corresponding air inlet blade is titled downwardly, a distance between a top end of the air outlet blade and the corresponding power module is less than a distance between a bottom end of the corresponding air outlet blade and the corresponding power module.

15. The charging device of claim 14, wherein the heat dissipation mechanism further comprises a rain detection member connected to the housing and a processor; the rain detection member is configured to detect whether a climate where the charging device is located is raining and output rain detection information; the processor communicates with the rain detection member and the plurality of the second driving parts; the processor is configured to receive the rain detection information and control the plurality of the second driving parts to switch on based on the received rain detection information.

16. The charging device of claim 10, wherein the plurality of the power modules is disposed between the air inlet opening and an air outlet opening of the housing; further comprises an air outlet member disposed in the housing; the air outlet member is located between the plurality of the power modules and the air outlet opening; the air outlet member is configured to drive the airflow to flow from the plurality of the power modules to the air outlet opening.

17. The charging device of claim 16, wherein the heat dissipation mechanism further comprises:
an air outlet louver to be connected to the housing and configured to shield the air outlet opening.

18. The charging device of claim 17, wherein the air outlet louver comprises a plurality of air outlet blades; the plurality of the air outlet blades is separated from each other; a distance between a top end of each of the plurality of the air outlet blades and the corresponding power module is less than a distance between a bottom end of the corresponding air outlet blade and the corresponding power module.
